(19) United States
(12) Patent Application Publication
(10) Pub. No.: US 2014/0217448 A1
(43) Pub. Date: Aug. 7, 2014

(54) SEMICONDUCTOR LIGHT EMITTING DEVICE

(71) Applicant: SAMSUNG ELECTRONICS CO., LTD., Suwon-si (KR)

(72) Inventors: Sung-joon KIM, Suwon-si, Gyeonggi-do (KR); Young-ho RYU, Suwon-si, Gyeonggi-do (KR); Tae-young PARK, Yongin-si, Gyeonggi-do (KR); Tae-sung JANG, Hwaseong-si, Gyeonggi-do (KR)

(73) Assignee: SAMSUNG ELECTRONICS CO., LTD., Suwon-si (KR)

(21) Appl. No.: 14/167,885

(22) Filed: Jan. 29, 2014

(30) Foreign Application Priority Data
Feb. 5, 2013 (KR) 10-2013-0012944

(51) Int. Cl. H01L 33/50

(52) U.S. Cl. CPC H01L 33/50
USPC 257/98

(57) ABSTRACT

There is provided a semiconductor light-emitting device having a small size and high light efficiency. The semiconductor light-emitting device includes a substrate; a light-emitting structure that includes a first conductive-type semiconductor layer, an active layer, and a second conductive-type semiconductor layer are formed on the substrate, wherein the light-emitting structure comprises a first region, a second region, and a light radiation surface on one of the first and second conductive-type semiconductor layers, wherein only the first conductive-type semiconductor layer remains on the substrate in the first region as a part of the second conductive-type semiconductor layer and a part of the active layer are removed, wherein the active layer is disposed between the first and second conductive-type semiconductor layers on the substrate in the second region, a fluorescent body that covers at least a part of the second region on the light radiation surface of the light-emitting structure, and a first electrode and a second electrode which are electrically respectively connected to the first and second conductive-type semiconductor layers so that the first and second electrodes may be connected to a different conductive-type semiconductor layer from each other, wherein the second electrode is formed in the first region on the light radiation surface of the light-emitting structure.

### CROSS-REFERENCE TO RELATED APPLICATIONS

This application claims the benefit to Korean Patent Application No. 10-2013-0012944, filed on Feb. 5, 2013, in the Korean Intellectual Property Office, the disclosure of which is incorporated herein in its entirety by reference.

### TECHNICAL FIELD

The inventive concept relates to a semiconductor light-emitting device, and more particularly, to a semiconductor light-emitting device that includes a fluorescent body that may enhance brightness of the semiconductor light-emitting device.

### BACKGROUND

A light-emitting diode (LED) is a semiconductor light source that changes an electrical signal into light through a p-n junction of a compound semiconductor. As LEDs have been increasingly used in various fields such as indoor or outdoor lighting, vehicle headlights, and back-light units (BLU) for display apparatuses, there is a need for developing a white LED that has high reliability and stability.

Such a white LED is usually developed by using a fluorescent body for an LED that may emit blue light with a short wavelength. Also, in order to completely convert blue light with a short wavelength into white light, it is necessary to increase an area that covers the fluorescent body. However, as a size of the semiconductor light-emitting device increases, the light efficiency of semiconductor light-emitting device may deteriorate.

### SUMMARY

According to an aspect of the inventive concept, there is provided a semiconductor light-emitting device, comprising: a substrate; a light-emitting structure that comprises a first conductive-type semiconductor layer, an active layer, and a second conductive-type semiconductor layer are formed on the substrate, wherein the light-emitting structure comprises a first region, a second region, and a light radiation surface on one of the first and second conductive-type semiconductor layers, wherein only the first conductive-type semiconductor layer remains on the substrate in the first region as a part of the second conductive-type semiconductor layer and a part of the active layer are removed, wherein the active layer is disposed between the first and second conductive-type semiconductor layers on the substrate in the second region; and a first electrode and a second electrode which are electrically respectively connected to the first and second conductive-type semiconductor layers so that the first and second electrodes may be connected to a different conductive-type semiconductor layer from each other; wherein the second electrode is formed on the first region on the light radiation surface of the light-emitting structure.

The second electrode may be disposed to be adjacent to an edge of an upper surface of the light-emitting structure.

The second electrode may be disposed to be adjacent to a side of the upper surface of the light-emitting structure.

The semiconductor light-emitting device may further include a fluorescent body that covers at least a part of the second region on the light radiation surface of the light-emitting structure, wherein the fluorescent body is formed to be separate from the side of the upper surface of the light-emitting structure which the second electrode is adjacent to.

The semiconductor light-emitting device may further include an insulating layer that covers a side of the active layer which is exposed at a boundary between the first and second regions.

The insulating layer may extend from the side of the active layer, which is exposed at the boundary between the first and second regions, so as to cover the first conductive semiconductor layer in the first region.

The semiconductor light-emitting device may further include a non-reflective metal layer which is formed on the insulating layer.

The semiconductor light-emitting device may further include a fluorescent body which covers at least a part of the second region on the light radiation surface of the light-emitting structure, extends from the boundary between the first and second regions to the first region, and thus, covers a part of the first region.

An edge of the first region of the fluorescent body may be separate from the boundary between the first and second regions and located within 20 μm from the boundary between the first and second regions.

The fluorescent body may further cover a part of the second electrode.

The second electrode may contact the first conductive-type semiconductor layer in the first region, and the first electrode may be electrically connected to the second conductive-type semiconductor layer, and the substrate may be a conductive substrate that functions as the first electrode.

The semiconductor light-emitting device may further include a reflective metal layer that is formed between the second conductive-type semiconductor layer and the first electrode.

The light-emitting structure may further include a third region, which is formed to be separate from the first region and, as a part of the second conductive-type semiconductor layer and a part of the active layer are removed, to expose the first conductive-type semiconductor layer, and a current dispersion layer that is formed on both the first and second regions of the light-emitting structure, wherein the first electrode is formed on the third region to contact the first conductive-type semiconductor layer, and the second electrode is connected to the second conductive-type semiconductor layer via the current dispersion layer.

According to another aspect of the inventive concept, there is provided a semiconductor light-emitting device, comprising: a conductive substrate; a light-emitting structure that comprises a first conductive-type semiconductor layer, an active layer, and a second conductive-type semiconductor layer are formed on the substrate, wherein the light-emitting structure comprises a first region and a second region, wherein only the first conductive-type semiconductor layer remains on the substrate in the first region as a part of the second conductive-type semiconductor layer and a part of the active layer are removed, wherein the active layer is disposed between the first and second conductive-type semiconductor layers on the substrate in the second region; an insulating layer that covers a side of the active layer which is exposed at a boundary between the first and second regions; a pad electrode that is formed on the first region and is electrically connected to the second conductive-type semiconductor layer; and a fluorescent body that covers the second regions, wherein the conductive electrode is electrically connected to the first conductive-type semiconductor layer.

The pad electrode may be disposed to be adjacent to an edge of an upper surface of the second conductive-type semiconductor layer, wherein the fluorescent body extends from the boundary between the first and second regions to the first region, covers a part of an upper surface of the second conductive-type semiconductor layer in the first region, and is formed to be separate from an edge of the upper surface of the second conductive-type semiconductor layer which the second electrode is adjacent to.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

Exemplary embodiments of the inventive concept will be more clearly understood from the following detailed description taken in conjunction with the accompanying drawings in which:

FIGS. 1 through 8 are cross-sectional views sequentially illustrating a method of manufacturing a semiconductor light-emitting device according to an embodiment of the inventive concept;

FIG. 9 is a plan view illustrating the semiconductor light-emitting device according to an embodiment of the inventive concept;

FIGS. 10 and 11 are respectively a cross-sectional view and a plan view illustrating a semiconductor light-emitting device according to an embodiment of the inventive concept;

FIGS. 12 and 13 are respectively a cross-sectional view and a plan view illustrating a semiconductor light-emitting device according to an embodiment of the inventive concept;

FIGS. 14 and 15 are respectively a cross-sectional view and a plan view illustrating a semiconductor light-emitting device according to an embodiment of the inventive concept;

FIGS. 16 and 17 are respectively a cross-sectional view and a plan view illustrating a semiconductor light-emitting device according to an embodiment of the inventive concept;

FIG. 18 is a cross-sectional view illustrating a semiconductor light-emitting device according to a modification of an embodiment of the inventive concept;

FIGS. 19 through 22 are cross-sectional views sequentially illustrating a method of manufacturing a semiconductor light-emitting device according to another embodiment of the inventive concept;

FIG. 23 is a plan view illustrating a semiconductor light-emitting device according to another embodiment of the inventive concept;

FIGS. 24 and 25 are cross-sectional views illustrating a semiconductor light-emitting package that includes a semiconductor light-emitting device according to an embodiment of the inventive concept;

FIGS. 26 and 27 are cross-sectional views illustrating a semiconductor light-emitting package that includes a semiconductor light-emitting device according to an embodiment of the inventive concept;

FIG. 28 is a diagram illustrating a dimming system that includes the semiconductor light-emitting device according to an embodiment of the inventive concept; and

FIG. 29 is a block diagram illustrating an optical processing system that includes the semiconductor light-emitting device according to an embodiment of the inventive concept.

### DETAILED DESCRIPTION

In the following detailed description, numerous specific details are set forth by way of embodiments in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The attached drawings for illustrating exemplary embodiments of the inventive concept are referred to in order to gain a sufficient understanding of configurations and effects of the inventive concept. However, the inventive concept may be embodied in many different forms and should not be construed as being limited to the embodiments set forth herein; rather, these embodiments are provided so that this disclosure will be thorough and complete, and will fully convey the concept of the inventive concept to those skilled in the art. In the drawings, the lengths and sizes of elements may be exaggerated for convenience of description. The proportions of each element may be reduced or exaggerated for clarity.

It will be understood that when an element is referred to as being “on” or “connected to” another element, it can be directly on or connected to the other element, or intervening elements may be present. In contrast, when an element or layer is referred to as being “directly on” or “directly connected to” another element, there are no intervening elements present. Other words used to describe the relationship between elements or layers should be interpreted in a like fashion (e.g., “between,” versus “directly between,” etc.).

While terms such as “first,” “second,” etc., may be used to describe various elements, these elements must not be limited to the above terms. The above terms are used only to distinguish one element from another. For example, a first element may be referred to as a second element, and similarly, a second element may be referred to as a first element without departing from the scope of the inventive concept.

An expression used in the singular encompasses the expression in the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are intended to include the possibility that one or more other features, numbers, steps, actions, elements, parts, or combinations thereof may exist or may be added.

Unless terms used in embodiments of the inventive concept are defined differently, the terms may be construed as having meanings known to those skilled in the art.

Hereinafter, the present inventive concept will be described more fully with reference to the accompanying drawings, in which exemplary embodiments of the inventive concept are shown.

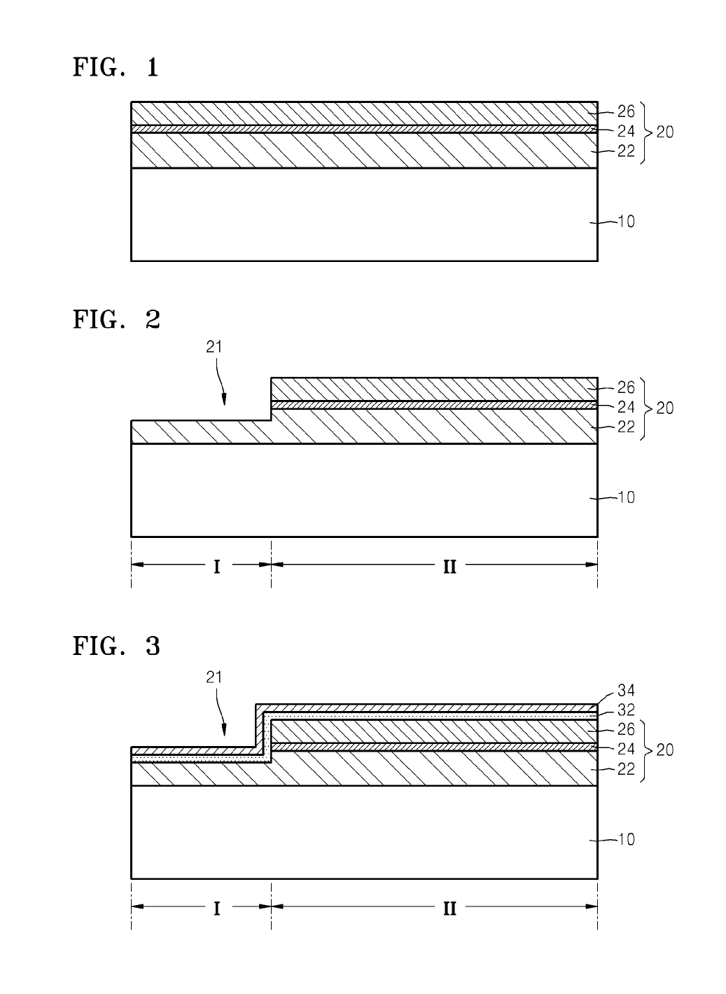

FIGS. 1 through 8 are cross-sectional views sequentially illustrating a method of manufacturing a semiconductor light-emitting device according to an embodiment of the inventive concept.

FIG. 1 is a cross-sectional view illustrating a process of forming a light-emitting structure 20 on a growth substrate 10.

Referring to FIG. 1, the light-emitting structure 20 is formed on the growth substrate 10. The growth substrate 10 may include at least one from among an insulating material, a conductive material, and a semiconductor material such as sapphire (Al₂O₃), silicon carbide (SiC), gallium nitride (GaN), gallium arsenic (GaAs), silicon (Si), germanium (Ge), zinc oxide (ZnO), magnesium oxide (MgO), aluminum nitride (AlN), boron nitride (BN), gallium phosphide (GaP), indium phosphide (InP), lithium-alumina (LiAl₂O₃), magnesium-aluminate (MgAl₂O₄). For example, sapphire, which has an electric insulation property, is a crystal that has Hexa-Rhombo R3c symmetry. Sapphire has a lattice constant of 13.001 Å and 4.758 Å respectively along a C-axis and an A-axis. Sapphire has a C (0001) surface, an A (1120) surface, an R (1102) surface and etc. In such a case, as the C plane comparatively facilitates growth of a nitride film and is stable at high temperature, sapphire may be mainly used as a substrate for nitride growth. Though not illustrated, an embossed pattern, which may reflect light, may be formed on an upper surface, a lower surface, or both the upper and lower surfaces. The embossed pattern may have various shapes such as a striped shape, a lens shape, a column shape, and a conical shape.

A buffer layer, for correcting a lattice mismatch between the growth substrate 10 and the light-emitting structure 20, may be further included at a side of the light-emitting structure 20 on the growth substrate 10. The buffer layer may be formed as a single layer or a multiple-layer. For example, the buffer layer may include at least one from among GaN, indium nitride (InN), aluminum nitride (AlN), indium gallium nitride (InGaN), aluminum gallium nitride (AlGaN), aluminum gallium indium nitride (AlGaInN), and aluminum indium nitride (AlInN) Additionally, an updoped semiconductor layer may be located at a side of the light-emitting structure 20 on the growth substrate 10. The updoped semiconductor layer may include GaN.

The light-emitting structure 20 may be located on the growth substrate 100. If the light-emitting structure 20 is formed of a plurality of conductive semiconductor layers based on the growth substrate 10, the light-emitting structure 20 may be formed of one from among an n-p bonding structure, an n-p junction structure, a p-n junction structure, an n-p-n junction structure, and a p-n-p junction structure. Hereinafter, a case in which the light-emitting structure 20 is formed of a n-p junction structure is described as an example.

The light-emitting structure 20 may include a first conductive-type semiconductor layer 22, an active layer 24, and a second conductive-type semiconductor layer 26 which are sequentially stacked. The light-emitting structure 20 may be formed by using, for example, electron beam evaporation, physical vapor deposition (PVD), chemical vapor deposition (CVD), plasma enhanced CVD (PECVD), plasma laser deposition (PLD), a dual-type thermal evaporator, sputtering, metal organic chemical vapor deposition (MOCVD), molecular beam epitaxy (MBE), hydride vapor shape epitaxy (HYPE), and so on.

The light-emitting structure 20 may be formed by growing a nitride semiconductor, for example, InN, AlN, InGaN, AlGaN, and InGaAlN. In addition to a nitride semiconductor, the light-emitting structure 20 may be formed by using a semiconductor, such as ZnO, zinc sulfide (ZnS), Zinc selenide (ZnSe), SiC, GaP, gallium-aluminum arsenide (GaAlAs), and aluminum indium gallium phosphide (AlInGaP).

When a voltage is applied to the light-emitting structure 20 in a forward direction, an electron located in a conduction band in the active layer 24 and a hole in a valence band are transited and recombined. Then, energy that corresponds to an energy gap is emitted as light. A wavelength of emitted light is determined according to a type of a material of the active layer 24. Additionally, the first conductive-type semiconductor layer 22 and the second conductive-type semiconductor layer 26 may have a function of providing an electron or a hole to the active layer 24 according to the applied voltage. The first conductive-type semiconductor layer 22 and the second conductive-type semiconductor layer 26 may include different impurities from each other, so that they may have different conductive types. For example, the first conductive-type semiconductor layer 22 may include n-type impurities, and the second conductive-type semiconductor layer 26 may include p-type impurities. In this case, the first conductive-type semiconductor layer 22 may provide an electron, and the second conductive-type semiconductor layer 26 may provide a hole. Conversely, a case in which the first conductive-type semiconductor layer 22 is a p-type and the second conductive-type semiconductor layer 26 is an n-type may also pertain to the scope of the inventive concept. The first conductive-type semiconductor layer 22 and the second conductive-type semiconductor layer 26 may include a Group III-V compound material, for example, a GaN material.

The first conductive-type semiconductor layer 22 may be an n-type semiconductor layer doped with an n-type dopant. For example, the first conductive-type semiconductor layer 22 may include n-type AlₓIn_{y}Ga_{z}N, where 0≦x≦1, 0≦y≦1, 0≦z≦1, and x+y+z=1. The n-type dopant may be at least one from among Si, Ge, tin (Sn), selenium (Se), and tellurium (Te).

The second conductive-type semiconductor layer 26 may be a p-type semiconductor layer doped with a p-type dopant. For example, the second conductive-type semiconductor layer 26 may include p-type AlₓIn_{y}Ga_{z}N, where 0≦x≦1, 0≦y≦1, 0≦z≦1, and x+y+z=1. The n-type dopant may be at least one from among Mg, zinc (Zn), calcium (Ca), strontium (Sr), beryllium (Be), and barium (Ba). Though not illustrated, an embossed pattern may be formed on an upper surface of the second conductive-type semiconductor layer 26, so that light is scattered, refracted, and thus, emitted outside.

The active layer 24 has a lower energy band-gap compared to the first conductive-type semiconductor layer 22 and the second conductive-type semiconductor layer 26. Thus, the active layer 24 may activate light emission. The active layer 24 may emit light of various wavelengths. For example, the active layer 24 may emit an infrared ray, an ultraviolet ray, and visible light. The active layer 24 may include a Group III-V compound material, for example, AlₓIn_{y}Ga_{z}N, where 0≦x≦1, 0≦y≦1, 0≦z≦1, and x+y+z=1, such as InGaN or AlGaN. Additionally, the active layer 24 may include a single-quantum well (SQW) or a multi-quantum well (MQW). The active layer 24 may have a structure in which quantum-well layers and quantum-barrier layers are stacked. The number of the quantum-well layers and the quantum-barrier layers may vary as needed according to design requirements. Additionally, the active layer 24 may include a GaN/InGaN/GaN MQW structure or a GaN/AlGaN/GaN MQW structure. However, this is only an example, and a wavelength of light emitted from the active layer 24 may vary with a material of the active layer 24. For example, if an amount of indium makes up about 22% of the active layer 24, blue light may be emitted. If an amount of indium makes up about 40% of the active layer 24, green light may be emitted. However, the scope of the inventive concept with regard to the material of the active layer 24 is not limited to the above description.

FIG. 2 is a cross-sectional view illustrating a process of removing the second conductive-type semiconductor layer and the active layer which are formed on a first region I of the light-emitting structure 20, according to an embodiment of the inventive concept.

Referring to FIG. 2, a part of the light-emitting structure 20 formed on the growth substrate 10 is removed. A region of the light-emitting structure 20 wherefrom a part of the second conductive-type semiconductor layer 26 and the active layer 24 are removed and only the first conductive-type semiconductor layer 22 remains may be the first region I A region where the active layer 24 is disposed between the first conductive-type semiconductor layer 22 and the second conductive-type semiconductor layer 26 may be the second region II.

That is, by removing the second conductive-type semiconductor layer 26 and the active layer 24 from the first region I of the light-emitting structure 20, a first recess 21 that exposes the first conductive-type semiconductor layer 22 may be formed. In order to remove the second conductive-type semiconductor layer 26 and the active layer 24 from the first region I, for example, inductively-coupled plasma reactive ion etching (ICP-RIE), wet-etching, or dry-etching may be used. In a process of removing the second conductive-type semiconductor layer 26 and the active layer 24, a part of the first conductive-type semiconductor layer 22 may be removed. However, a layer below the first conductive-type semiconductor layer 22, for example, the growth substrate 10 is not exposed.

FIG. 3 is a cross-sectional view illustrating a process of forming an insulating layer and a non-reflective metal layer on the light-emitting structure 20 according to an embodiment of the inventive concept.

Referring to FIG. 3, an insulating layer 32 is formed on the light-emitting structure 20. The insulating layer 32 may be formed of an oxide or nitride, for example, silicon oxide (SiOₓ) or silicon nitride (SiN). The insulating layer 32 may be formed to cover both a boundary between the first region I and the second region II and an exposed surface of the light-emitting structure 20 in the first region I and the second region II. Alternatively, the insulating layer 32 may be formed to selectively cover both the boundary between the first region I and the second region II, that is, a side inside the first recess 21 and the exposed surface of the light-emitting structure 20 in the first region I.

A non-reflective metal layer 34 may be further disposed on the insulating layer 32. The non-reflective metal layer 34 may be formed of a metal material that does not reflect light and that may absorb light which is emitted from the active layer 24 and has a predetermined wavelength. The non-reflective metal layer 34 may be formed of a metal material, such as titanium (Ti), titanium tungsten (TiW), and titanium nitride (TiN).

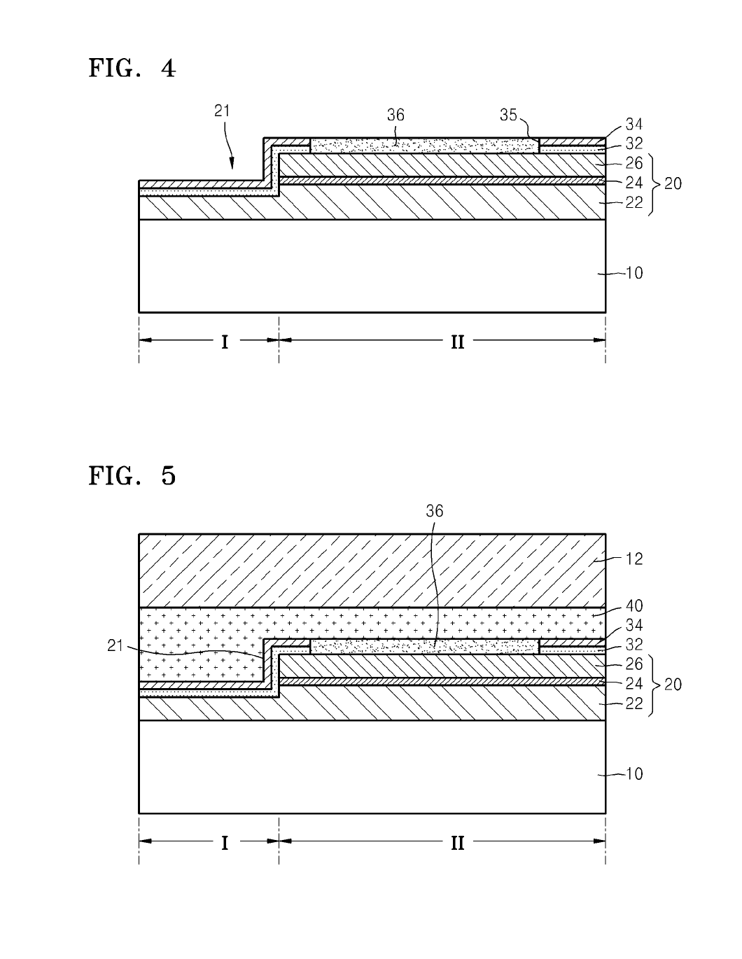

FIG. 4 is a cross-sectional view illustrating a process of forming a reflective metal layer on the light-emitting structure according to an embodiment of the inventive concept.

Referring to FIG. 4, a part of the insulating layer 32 or a part of the insulating layer 32 and the non-reflective metal layer 34 is removed, and thus, an opening 35 for exposing the second conductive-type semiconductor layer 26. Then, a reflective metal layer 36 is formed to fill the opening 35. The reflective metal layer 36 may include aluminum (Al), silver (Ag), an alloy thereof, Ag-based oxide (Ag—O), or an Ag—Pd—Cu (APC) alloy. Additionally, the reflective metal layer 36 may further include at least one from among rhodium (Rh), copper (Cu), palladium (Pd), nickel (Ni), ruthenium (Ru), iridium (Ir), Ti, and platinum (Pt).

Even after the opening is formed, the insulating layer 32 may cover the boundary between the first region I and the second region II, that is, a side of the active layer 24 which is exposed at a side of the first recess 21. The insulating layer 32 may cover also the boundary between the first region I and the second region II, that is, a side of the second conductive-type semiconductor layer 26 which is exposed at a side inside the first recess 21. The insulating layer 32 may extend from the boundary between the first region I and the second region II to the first conductive-type semiconductor layer 22 on the first region I. Accordingly, the insulating layer 32 may cover both a surface of the first conductive-type semiconductor layer 22, which is exposed inside the first recess 21, and a surface of the active layer 24.

FIG. 5 is a cross-sectional view illustrating a process of attaching a support substrate 12 according to an embodiment of the inventive concept.

Referring to FIG. 5, the support substrate 12 is attached to the light-emitting structure 20 by using a bonding metal layer 40. The bonding metal layer 40 may be formed to cover the insulating layer 32 and the reflective metal layer 36, or the non-reflective metal layer 34 and the reflective metal layer 36 which are formed on the light-emitting structure 20. The bonding metal layer 40 may be formed of, for example, gold (Au), Sn, Ni, or an alloy thereof. The bonding metal layer 40 may be formed to have a flat upper surface so as to be attached to the support substrate 12. Otherwise, when the support substrate 12 is attached to the bonding metal layer 40, a pressure may be applied to the bonding metal layer 40 by the support substrate 12. Thus, the bonding metal layer 40 may have a flat upper surface. The support substrate 12 may be formed of a conductive material. The support substrate 12 may be formed of, for example, Si or silicon aluminide (SiAl).

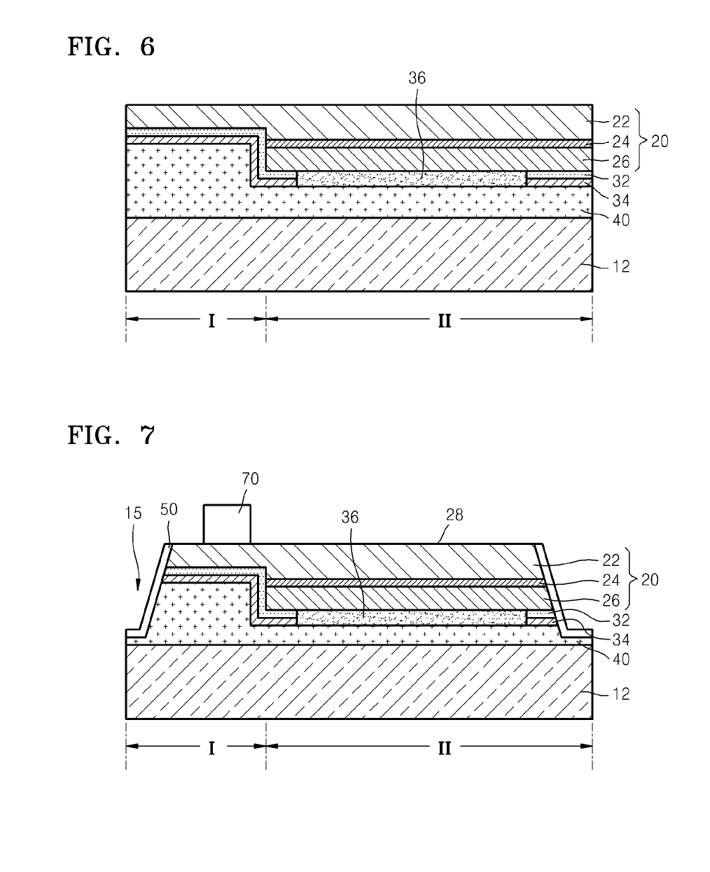

FIG. 6 is a cross-sectional view illustrating a process of removing the growth substrate 12 according to an embodiment of the inventive concept.

Referring to FIGS. 5 and 6, the growth substrate 10 is removed, and the light-emitting structure 20 is turned upside down so that the support substrate 12 faces downwards. In order to remove the growth substrate 10, for example, a laser lift-off (LLO) method may be used.

FIG. 7 is a cross-sectional view illustrating a process of forming a pad electrode 70 according to an embodiment of the inventive concept.

Referring to FIG. 7, the pad electrode 70, which is electrically connected to the first conductive-type semiconductor layer 22, is formed on the first region I. The pad electrode 70 may be formed of one or more layers that include Au, Ag, Al, Ni, Cr Pd, Cu, or an alloy thereof, by using a method such as evaporation, sputtering, or plating. Additionally, the pad electrode 70 may include eutectic metal, for example, gold-tin (AuSn) or tin-bismuth (SnBi). The pad electrode 70 may be disposed to be adjacent to an edge of an upper surface of the light-emitting structure 20.

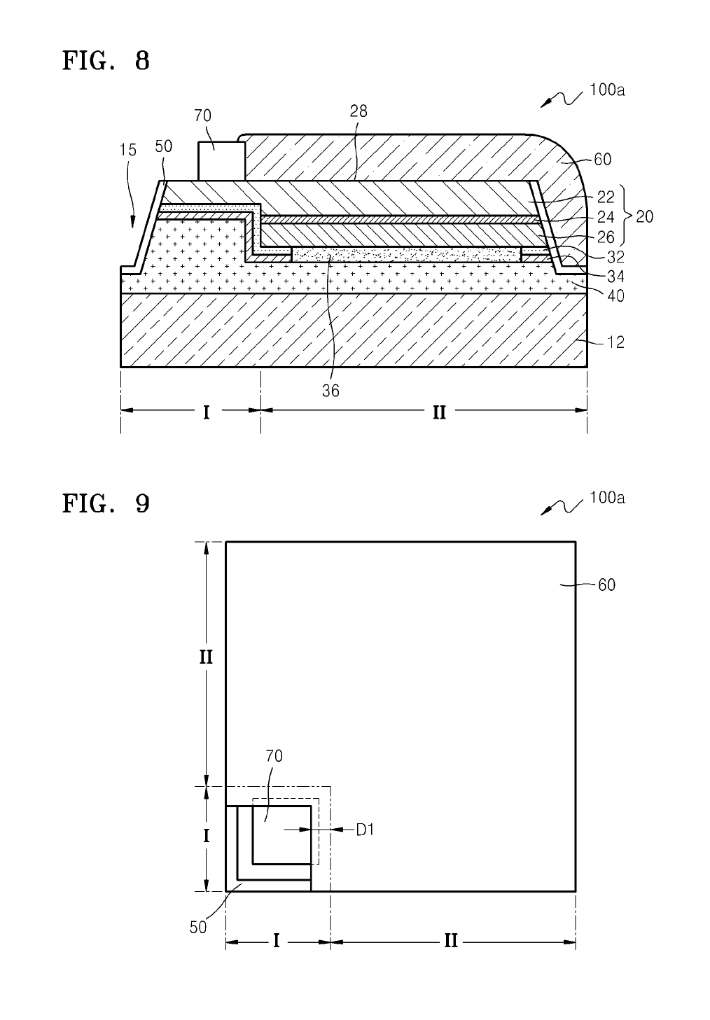

The pad electrode 70 may be formed so that at least a part of the pad electrode 70 overlaps with the first region I. This will be described later in detail, by referring to FIGS. 8 through 17. For example, the pad electrode 70 may formed so that the pad electrode 70 entirely overlaps with the first region I, and is separate from the second region II. The pad electrode 70 may also be formed so that the pad electrode 70 entirely overlaps with the first region I, and contacts the boundary between the first region I and the second region II. Alternatively, the pad electrode 70 may formed so that the pad electrode 70 overlaps with the first region I, and also overlaps partially with the second region II.

The support substrate 12 may function as a first electrode of the light-emitting structure 20, and the pad electrode 70 may function as a second electrode of the light-emitting structure 20. Alternatively, the support substrate 12 and the bonding metal layer 40 may function as the first electrode of the light-emitting structure 20. That is, the support substrate 12 may be electrically connected to the second conductive-type semiconductor layer 26, and the pad electrode 70 may be electrically connected to the first conductive-type semiconductor layer 22 so that an electrode or a hole may be provided to the active layer 24.

Light emitted from the active layer 24 may be emitted the outside via a light radiation surface 28 of the first conductive-type semiconductor layer 22.

Additionally, a trench 15 may be formed to separate a plurality of the light-emitting structures 20 that are formed together. A protective layer 50 may be formed inside the trench 15. The protective layer 50 may be formed of an insulating material or a material that has high reflectivity. Alternatively, the trench 15 may be filled with an insulating material so as to function as a device isolation layer.

FIG. 8 is cross-sectional view illustrating a process of forming a fluorescent body 60 according to an embodiment of the inventive concept.

Referring to FIG. 8, a semiconductor light-emitting device 100a is formed by covering the light radiation surface 28 in the second region II with the fluorescent body 60. The fluorescent body 60 may convert part of or all light that is emitted from the light-emitting structure 20, and is not specially limited. The fluorescent body 60 may be formed of a fluorescent material that may implement white light by converting light that is emitted from the light-emitting structure 20. A material of the fluorescent body 60 may be determined according to a wavelength of light emitted from the light-emitting structure 20.

The fluorescent body 60 may be formed of one material from among a yttrium aluminum garnet (YAG)-based material, a terbium aluminum garnet (TAG)-based material, a sulfide-based material, a nitride-based material, or a quantum-point fluorescent material. For example, the fluorescent body 60 may be formed of Y₃Al₅O₁₂:Ce³⁺ (YAG:Ce), M₂Si₅N₈:Eu²⁺ in which Eu²⁺ ion is applied as an active agent, MS where M is alkaline earth metal, CaAlSiN₃:Eu³⁺, (Sr, Ca)AlSiN₃:Eu, Ca₃(Sc,Mg)₂Si₃O₁₂:Ce, or CaSc₂Si₃O₁₂:Ce, CaSc₂O₄:Ce. The quantum-point fluorescent material may be formed of cadmium selenide (CdSe), cadmium telluride (CdTe), zinc selenide (ZnSe), indium gallium phosphide (InGaP), or InP particles.

If filler particles are included in the fluorescent body 60, the filler particles may have a size of about 5 to 90 μm. The filler particles may be formed of titanium dioxide (TiO₂), silicon dioxide (SiO₂), aluminum oxide (Al₂O₃), MN, or a combination thereof. Polymer resin, included in the fluorescent body 60, may be formed of transparent resin. Polymer resin, included in the fluorescent body 60, may be formed of epoxy resin, silicon resin, polymethyl methacrylate (PMMA), polystyrene, polyurethane, or benzoguanamine resin. The fluorescent body 60 may be formed by using a spray coating process of spraying a fluorescent body mixture that includes resin, filler particles, and a solvent, and a hardening process. Alternatively, the fluorescent body 60 may be formed to have a film shape and be attached to the light radiation surface 28.

FIG. 9 is a plan view illustrating a semiconductor light-emitting device according to an embodiment of the inventive concept. Specifically, FIG. 9 is a plan view illustrating the semiconductor light-emitting device 100a shown in FIG. 8.

Referring to FIGS. 8 and 9, the pad electrode 70 may be formed to be separate from the boundary between the first region I and the second region II and overlap only with the first region I. The fluorescent body 60 covers the light radiation surface 28 in the second region II, extends from the boundary between the first region I and the second region II to the first region I, and thus, may cover a part of the first region I.

An edge of the fluorescent body 60 in the first region I may be separate from the boundary between the first region I and the second region II for a first distance D1. The first distance D1 may be, for example, greater than 0 μm and equal to or smaller than 20 μm. That is, the fluorescent body 60 may extend from the boundary between the first region I and the second region II to within 20 μm of the first region I. The fluorescent body 60 extends from the boundary between the first region I and the second region II to the first region I for a predetermined distance. Thus, all light emitted from the active layer 24 and passes through the light radiation surface 28 may pass through the fluorescent body 60. As a part of the first region I where the fluorescent body 60 is not formed is separate from an upper part of the active layer 24 by the first distance D1, light that is emitted from the active layer 24 may not reach the part of the first region 1.

Light which moves toward the support substrate 12 from among light emitted from the active layer 24 may be reflected by the reflective metal layer 36, and thus, may reach the light radiation surface 28. On the other hand, light which is emitted from the active layer 24 and moves toward the first region I of the support substrate 12, may be absorbed by the non-reflective metal layer 34. Light that is reflected by an upper surface of the first conductive-type semiconductor layer 22 and moves toward the first region I, from among light which is emitted from the active layer 24 and directs toward the light radiation surface 28, may also be absorbed by the non-reflective metal layer 34. On the other hand, light that is emitted from the active layer 24 and moves toward a lower surface of the pad electrode 70 may be absorbed by the pad electrode 70 or may be reflected by a lower surface of the pad electrode 70 and absorbed by the non-reflective metal layer 34.

The pad electrode 70 may be formed on the first region at a side of the light radiation layer 28 on the light-emitting structure 20. The pad electrode 70 may be disposed to be adjacent to an edge of an upper surface of the light-emitting structure 20. Additionally, the pad electrode 70 may be disposed to be adjacent to an edge of an upper surface of the light-emitting structure 20, that is, an area where two adjacent sides of an upper surface of the light-emitting structure 20 meet.

The fluorescent body 60 may be formed to be separate from the edge of the upper surface of the light-emitting structure 20 that is adjacent to the pad electrode 70. Additionally, the fluorescent body 60 may cover a part of the pad electrode 70. The fluorescent body 60 may not be formed on a side of the pad electrode 70 which is adjacent to the edge of the light-emitting structure 20, and may be formed only on a side of the pad electrode 70 that is adjacent to the second region II. That is, the fluorescent body 60 does not cover the entire edge of the pad electrode 70 and covers only an edge of a side that is adjacent to the second region II.

An exposed area of the pad electrode 70 may be larger, compared to a case when the fluorescent body 60 covers an entire edge of the pad electrode 70. Accordingly, a margin for connecting a bonding wire to the pad electrode 70 may be ensured. Additionally, a size of the pad electrode 70 may be formed to be relatively small, compared to the case when the fluorescent body 60 covers an entire edge of the pad electrode 70. Accordingly, an upper surface of the light-emitting structure 20 which is covered by the pad electrode 70 decreases. Thus, the light efficiency of the semiconductor light-emitting device 100a may be improved. Otherwise, as a size of the pad electrode 70 may be formed relatively small, a size of a semiconductor light-emitting device which one, which has the same optical power, may decrease.

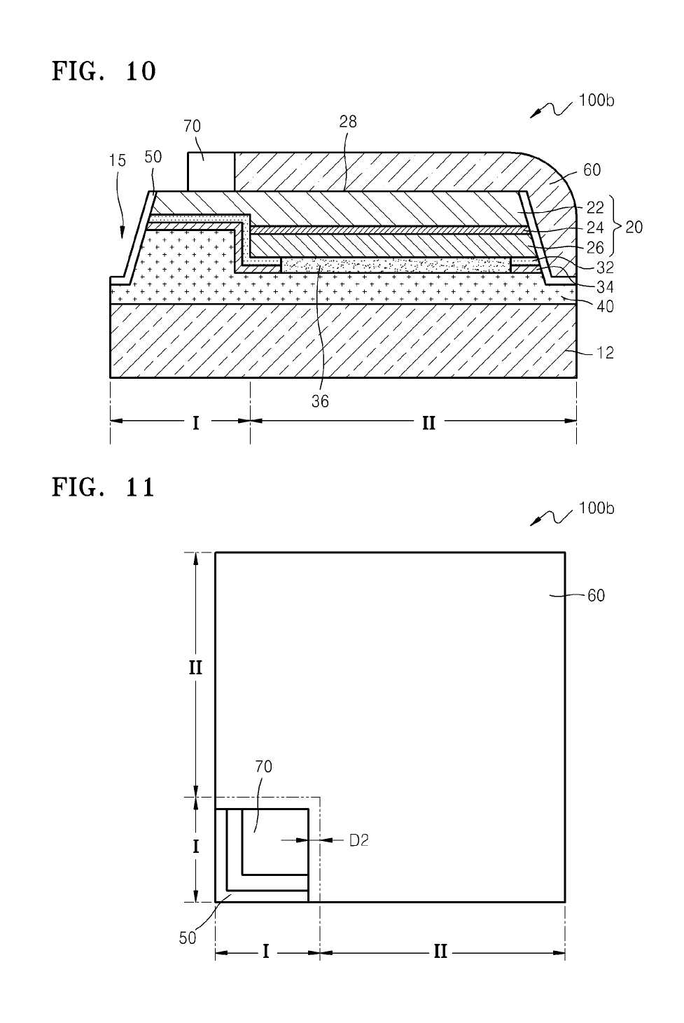

FIGS. 10 and 11 are respectively a cross-sectional view and a plan view illustrating a semiconductor light-emitting device according to an embodiment of the inventive concept.

Referring to FIGS. 10 and 11 together, the pad electrode 70 of a semiconductor light-emitting device 100b may be formed to be separate from the boundary between the first region I and the second region II, and overlap only with the first region I. The fluorescent body 60 covers the light radiation surface 28 in the second region II, extends from the boundary between the first region I and the second region II to the first region I, and thus, may cover a part of the first region I.

An edge of the fluorescent body 60 in the first region I may be separate from the boundary between the first region I and the second region II for a second distance D2. The second distance D2 may be, for example, greater than 0 μm and equal to or smaller than 20 μm. That is, the fluorescent body 60 may extend from the boundary between the first region I and the second region II to within 20 μm of the first region I. The fluorescent body 60 extends from the boundary between the first region I and the second region II to the first region I for a predetermined distance. Thus, all light that is emitted from the active layer 24 and passes through the light radiation surface 28 may pass through the fluorescent body 60. As a part of the first region I on which the fluorescent body 60 is not formed is separate from an upper part of the active layer 24 for the second distance D2, light that is emitted from the active layer 24 may not reach the part of the first region 1.

Unlike the semiconductor light-emitting device 100a shown in FIGS. 8 and 9, the fluorescent body 60 of the semiconductor light-emitting device 100b shown in FIGS. 10 and 11 may not be formed on the pad electrode 70, and may be formed to be adjacent to a side of the pad electrode 70. Specifically, the fluorescent body 60 may be formed to cover a side of the pad electrode 70 that faces the boundary between the first region I and the second region II.

That is, the distance D2 may be a distance by which the boundary between the first region I and the second region II and the pad electrode 70 are separated from each other.

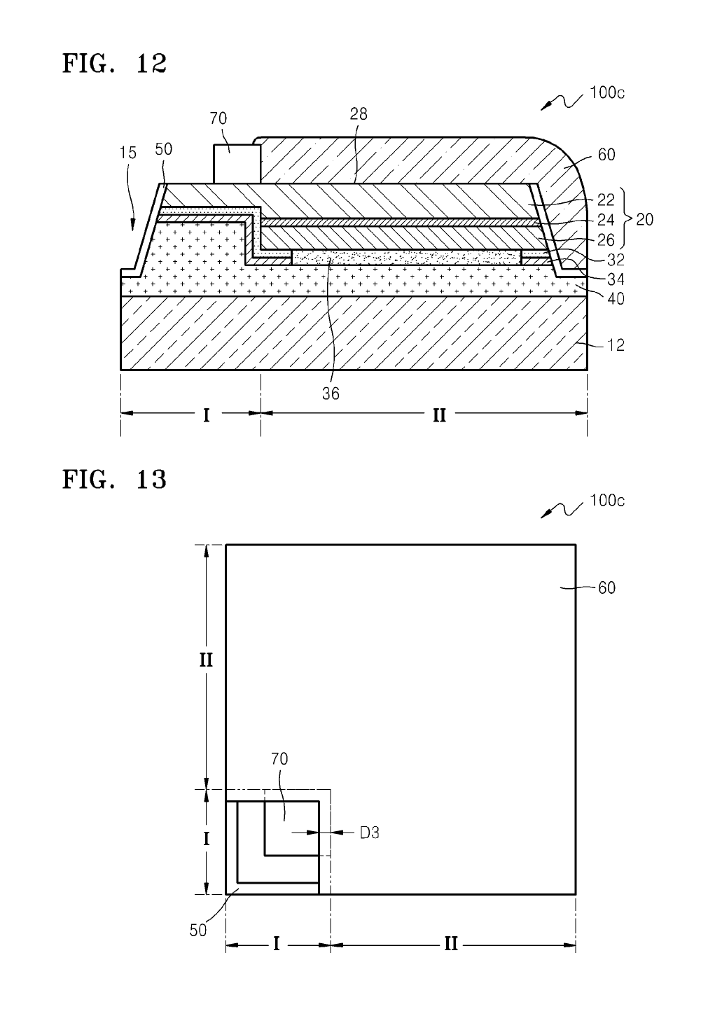

FIGS. 12 and 13 are respectively a cross-sectional view and a plan view illustrating a semiconductor light-emitting device according to an embodiment of the inventive concept.

Referring to FIGS. 12 and 13 together, the pad electrode 70 of a semiconductor light-emitting device 100c may be adjacent to the boundary between the first region I and the second region II, and may overlap only with the first region I. The fluorescent body 60 covers the light radiation surface 28 in the second region II, extends from the boundary between the first region I and the second region II to the first region I, and thus, may cover a part of the first region I.

An edge of the fluorescent body 60 in the first region I may be separate from the boundary between the first region I and the second region II for a third distance D3. The second distance D3 may be, for example, greater than 0 μm and equal to or smaller than 20 μm. That is, the fluorescent body 60 may extend from the boundary between the first region I and the second region II to within 20 μm of the first region I. The fluorescent body 60 extends from the boundary between the first region I and the second region II to the first region I by a predetermined distance. Thus, all light that is emitted from the active layer 24 and passes through the light radiation surface 28 may pass through the fluorescent body 60. As a part of the first region I on which the fluorescent body 60 is not formed, is separate from an upper part of the active layer 24 for the third distance D3 light that is emitted from the active layer 24 may not reach the part of the first region 1.

The fluorescent body 60 may further cover a part of the pad electrode 70. The fluorescent body 60 may not be formed on a side of the pad electrode 70 which is adjacent to the edge of the pad electrode 70, and may be formed only on a side of the pad electrode 70 that is adjacent to the second region II. That is, the fluorescent body 60 may not cover the entire edge of the pad electrode 70 and may cover only an edge of a side that is adjacent to the second region II.

That is, the third distance D3 may be a width of a part that covers the pad electrode 70.

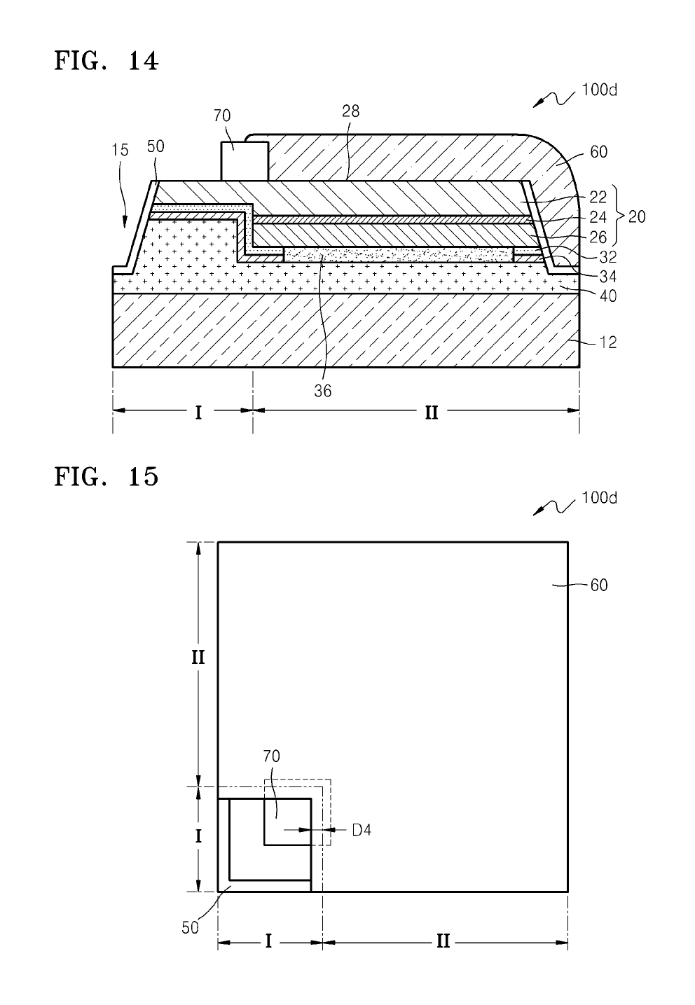

FIGS. 14 and 15 are respectively a cross-sectional view and a plan view illustrating a semiconductor light-emitting device 100d according to an embodiment of the inventive concept.

Referring to FIGS. 14 and 15 together, the pad electrode 70 of the semiconductor light-emitting device 100d may be formed to partially overlap with the second region II, through the boundary between the first region I and the second region II. The fluorescent body 60 covers the light radiation surface 28 in the second region II, extends from the boundary between the first region I and the second region II to the first region I, and thus, may cover a part of the first region I.

An edge of the fluorescent body 60 in the first region I may be separate from the boundary between the first region I and the second region II by a fourth distance D4. The fourth distance D4 may be, for example, greater than 0 μm and equal to or smaller than 20 μm. That is, the fluorescent body 60 may extend from the boundary between the first region I and the second region II to within 20 μm of the first region I. The fluorescent body 60 extends from the boundary between the first region I and the second region II to the first region I by a predetermined distance. Thus, all light that is emitted from the active layer 24 and passes through the light radiation surface 28 may pass through the fluorescent body 60. As a part of the first region I on which the fluorescent body 60 is not formed is separate from an upper part of the active layer 24 for the fourth distance D4, light that is emitted from the active layer 24 may not reach the part of the first region 1.

The fluorescent body 60 may further cover a part of the pad electrode 70. The fluorescent body 60 may not be formed on a side of the pad electrode 70 which is adjacent to the edge of the pad electrode 70, and may be formed only on an area on which the pad electrode 70 is formed in the second region II and on a side of the pad electrode 70 that is adjacent to the second region II. That is, the fluorescent body 60 may not cover the entire edge of the pad electrode 70.

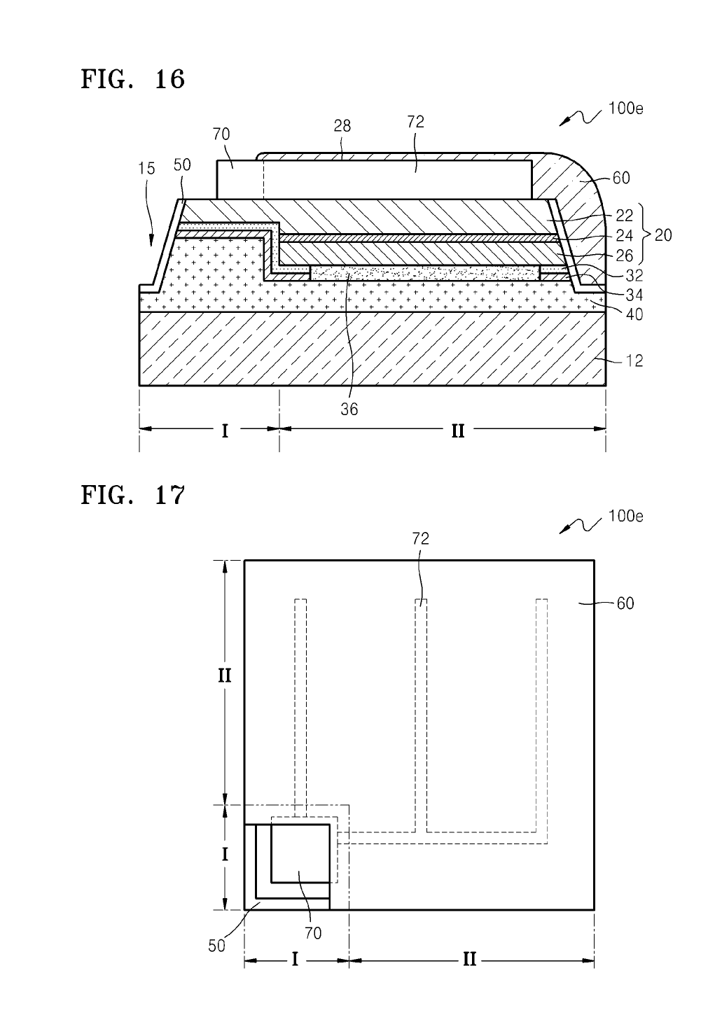

FIGS. 16 and 17 are respectively a cross-sectional view and a plan view illustrating a semiconductor light-emitting device 100e according to an embodiment of the inventive concept. Specifically, FIG. 16 is a cross-sectional view of the semiconductor light-emitting device taken along the pad electrode 70 and a conductive finger 72 of FIG. 17.

Referring to FIGS. 16 and 17, the semiconductor light-emitting device 100e is electrically connected to the pad electrode 70 on the light-emitting structure 20, and may further include a conductive finger 72 that extends to the second region II.

The semiconductor light-emitting device 100e, shown in FIGS. 16 and 17, is formed by further forming on the semiconductor light-emitting device 100a, shown in FIGS. 8 and 9. Thus, repeated description thereof will not be provided.

The fluorescent body 60 may be formed to cover the entire conductive finger 72.

Additionally, though not illustrated, the conductive finger 72 may be further formed on the semiconductor light-emitting devices 100b through 100d, shown in FIGS. 10 through 15.

FIG. 18 is a cross-sectional view illustrating a semiconductor light-emitting device 100f according to a modification of an embodiment of the inventive concept.

Referring to FIG. 18, an embossed structure 22 may be formed on an upper surface of the first conductive-type semiconductor layer 22, that is, the light radiation surface 28 of the semiconductor light-emitting device 100f. The embossed structure 22a may be formed by fabricating an upper surface of the first conductive-type semiconductor layer 22. Alternatively, the embossed structure 22a may be formed by forming an embossed pattern on an upper surface of the growth substrate, shown in FIG. 1, and transferring the embossed pattern to the first conductive-type semiconductor layer 22. The embossed structure 22a may scatter and refract light, and thus, improve the efficiency of light emission of semiconductor light-emitting device 100f.

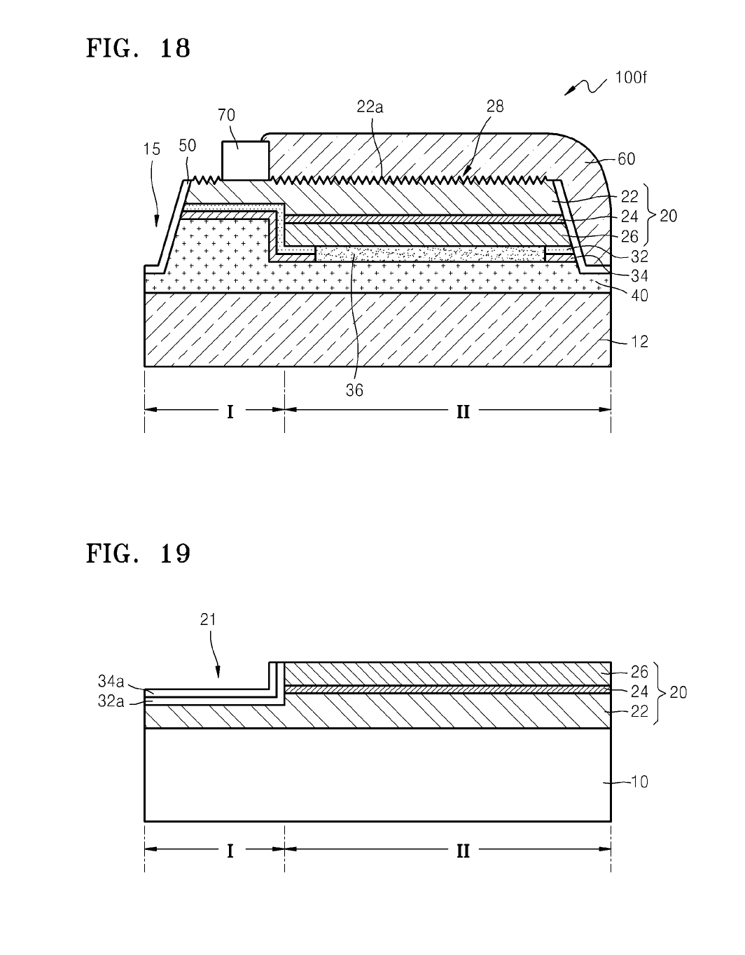

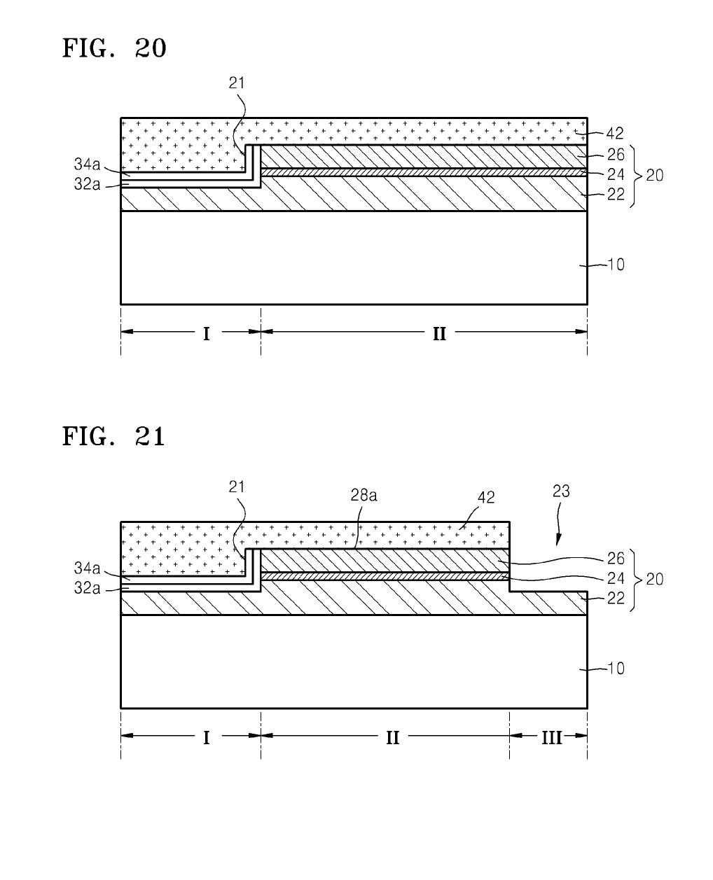

FIGS. 19 through 22 are cross-sectional views sequentially illustrating a method of manufacturing a semiconductor light-emitting device according to another embodiment of the inventive concept.

FIG. 19 is a cross-sectional view illustrating a process of forming an insulating layer and a non-reflective metal layer on the light-emitting structure 20 according to an embodiment of the inventive concept. Specifically, FIG. 19 is a cross-sectional view illustrating a process which is performed after the operations described with respect to FIGS. 1 and 2 are completed.

Referring to FIG. 19, an insulating layer 32a for covering an inside a first recess 21 is formed.

The insulating layer 32a may be formed of an oxide or nitride, for example, SiOₓ or SiN. The insulating layer 32a may be formed to cover both the boundary between the first region I and the second region II and an exposed surface of the light-emitting structure 20 in the first region I.

A non-reflective metal layer 34a may be further formed on the insulating layer 32a. The non-reflective metal layer 34a may be formed to cover a surface of the insulating layer 32a that is formed inside the first recess 21 of the non-reflected metal layer 34a. The non-reflective metal layer 34a may be formed of a metal material, such as Ti, TiW, and TiN.

Unlike in FIG. 1, the light-emitting structure 20 on the growth substrate 10 shown in FIG. 19 may further include a reflective layer for reflecting light that is emitted from the light-emitting structure 20.

FIG. 20 is a cross-sectional view illustrating a process of forming a current dispersion layer 42 according to another embodiment of the inventive concept.

Referring to FIG. 20, the current dispersion layer 42 for covering the light-emitting structure 20 is formed. The current dispersion layer 42 may include a transparent conductive material, and may be referred to as a transparent electrode layer. The current dispersion layer 42 may include a metal. For example, the current dispersion layer 42 may be a multiple layer formed of includes Ni and Au. Additionally, the current dispersion layer 42 may include oxide. For example, the current dispersion layer 42 may include at least one from among indium tin oxide (ITO), indium zinc oxide (IZO), indium zinc tin oxide (IZTO), aluminum zinc oxide (AZO), indium aluminum zinc oxide (IAZO), gallium zinc oxide (GZO), indium gallium oxide (IGO), indium gallium zinc oxide (IGZO), indium gallium tin oxide (IGTO), aluminum tin oxide (ATO), indium tungsten oxide (IWO), copper indium oxide (CIO), magnesium indium oxide (MIO), MgO, ZnO, indium oxide (In₂O₃), TiTaO₂, TiNbO₂, titanium oxide (TiOₓ), ruthenium (RuOₓ), and iridium oxide (IrOₓ). The current dispersion layer 42 may be formed, for example, by using evaporation or sputtering. Additionally, an embossed pattern, which is similar to the embossed structure 22a that is formed on an upper surface of the first conductive-type semiconductor layer 22 shown in FIG. 18, may be formed on an upper surface of the current dispersion layer 42. The embossed pattern may be formed so that light is scattered and refracted thereon, and thus, emitted to the outside.

FIG. 21 is a cross-sectional view illustrating a process of forming a mesh area on the light-emitting structure 20 according to another embodiment of the inventive concept.

Referring to FIGS. 20 and 21, a second recess 23 is formed in a mesh area that is formed by removing a part of the second conductive-type semiconductor layer 27 and the active layer 24 from a part of the second region II. Only the first conductive-type semiconductor layer 23 remains on the mesh area. Thus, the mesh area may be referred to as a third region III, instead of a part of the second region II. The first conductive-type semiconductor layer 22 may be exposed in the third region III.

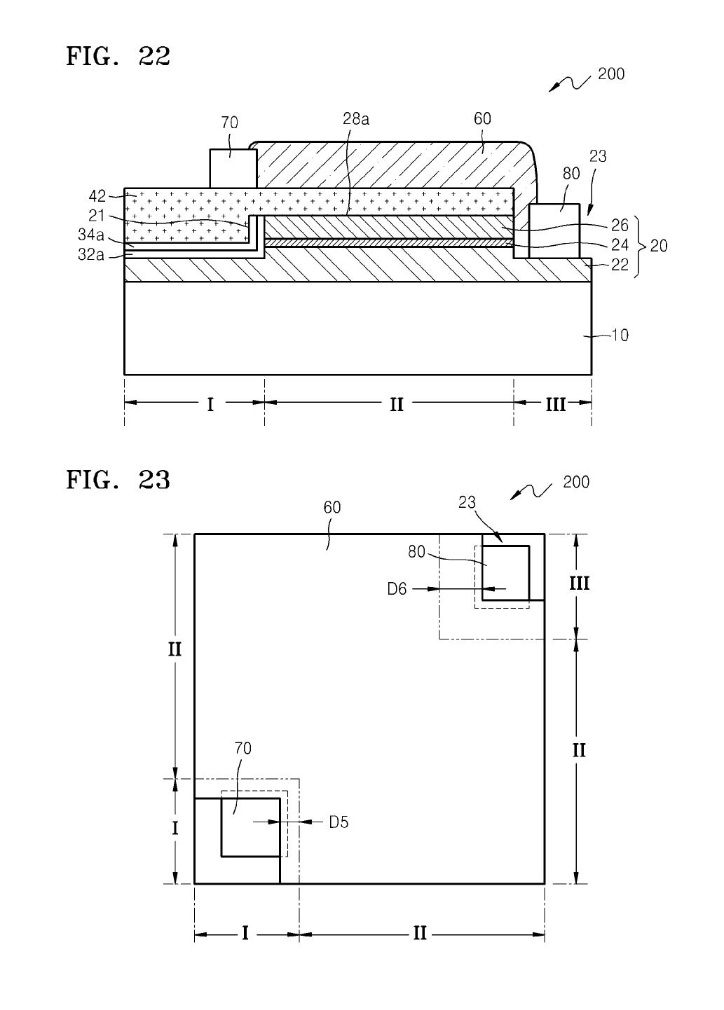

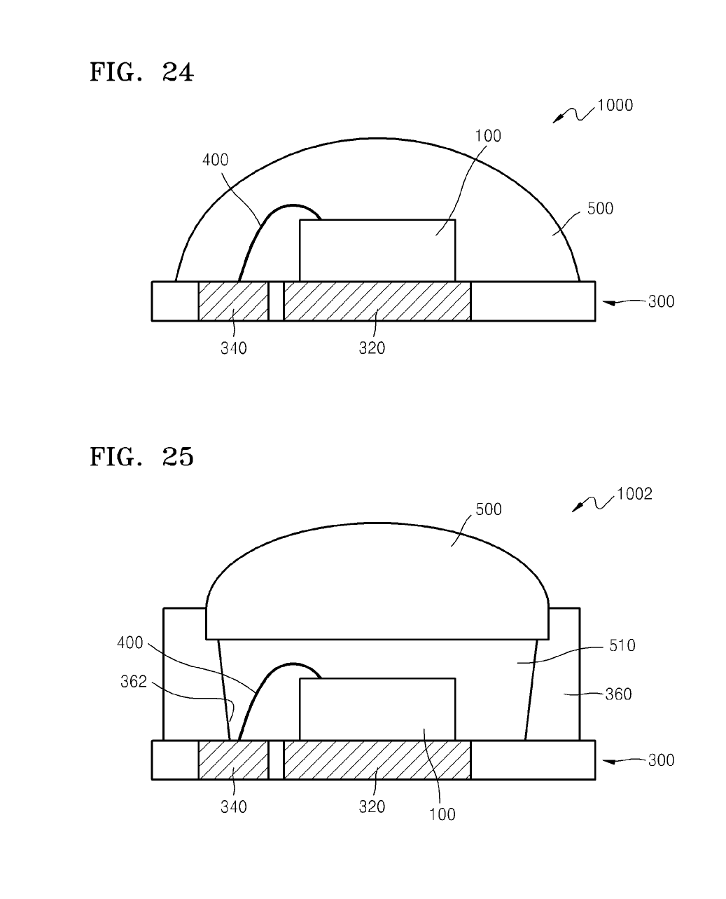

FIGS. 22 and 23 are a cross-section view and a plan view illustrating a semiconductor light-emitting device 200 according to another embodiment of the inventive concept.

Referring to FIGS. 22 and 23, the semiconductor light-emitting device 200 is formed by forming a first pad electrode 80, a second pad electrode 70, and the fluorescent body 60. The first pad electrode 80 may be formed on the first conductive-type semiconductor layer 22 in the third region III, so as to be electrically connected to the first conductive-type semiconductor layer 22. The second pad electrode 70 may be formed on the current dispersion layer 42 in the second region II so as to be electrically connected to the second conductive-type semiconductor layer 26. The fluorescent body 60 may be formed on the current dispersion layer 42 in the second region II.

The first pad electrode 80 may function as a first electrode of the light-emitting structure 20, and the second pad electrode 70 may function as a second electrode of the light-emitting structure 20. Alternatively, the second pad electrode 70 and the current dispersion layer 42 may function as the second electrode of the light-emitting structure 20. That is, the first pad electrode 80 may be electrically connected to the first conductive-type semiconductor layer 22, and the second pad electrode 70 may be electrically connected to the second conductive-type semiconductor layer 26 so that an electrode or a hole may be provided to the active layer 24.

A relationship between the second pad electrode 70, the fluorescent body 60, the first region I, and the second region II may be similar to that between the pad electrode 70, the fluorescent body 60, the first region I, and the second region II which are shown in FIG. 9. That is, the second pad electrode 70 may be formed to be separate from the boundary between the first region I and the second region II and overlap only with the first region I. The fluorescent body 60 covers a light radiation surface 28a in the second region II, extends from the boundary between the first region I and the second region II to the first region I, and thus, may cover a part of the first region I.

An edge of the fluorescent body 60 in the first region I may be separate from the boundary between the first region I and the second region II by a fifth distance D5. The fifth distance D5 may be, for example, greater than 0 μm and equal to or smaller than 20 μm. That is, the fluorescent body 60 may extend from the boundary between the first region I and the second region II to within 20 μm of the first region I.

A relationship between the first pad electrode 80, the fluorescent body 60, the second region II, and the third region III may be similar to that between the pad electrode 70, the fluorescent body 60, the first region I, and the second region II which are shown in FIG. 9. That is, the first pad electrode 80 may be formed to be separate from the boundary between the second region II and the third region III and overlap only with the third region III. The fluorescent body 60 covers the light radiation surface 28a in the second region II, extends from the boundary between the second region II and the third region III to the third region III, and thus, may cover a part of the third region III.

An edge of the fluorescent body 60 in the third region III may be separate from the boundary between the first region I and the second region II by a fifth distance D5. The fifth distance D5 may be, for example, greater than 0 μm and equal to or smaller than 20 μm. That is, the fluorescent body 60 may extend from the boundary between the first region I and the second region II to within 20 μm of the first region I.

Through not illustrated, the second pad electrode 70 and the fluorescent body 60 of the semiconductor light-emitting device 200 may be modified similarly to the second pad electrode 70 and the fluorescent body 60 of the semiconductor light-emitting devices 100b through 100e shown in FIGS. 10 through 17.

Additionally, through not illustrated, the first pad electrode 80 and the fluorescent body 60 of the semiconductor light-emitting device 200 may be modified similarly to the pad electrode 70 and the fluorescent body 60 of the semiconductor light-emitting devices 100b, shown in FIGS. 10 and 11.

The semiconductor light-emitting devices 100a through 100f shown in FIGS. 8 through 18 include the support substrate 12, and the semiconductor light-emitting device 200 includes the growth support 10. Thus, the support substrate 12 and the growth support 10 may be respectively referred to as a substrate.

Additionally, the semiconductor light-emitting devices 100a through 100e shown in FIGS. 8 through 18 may include the light radiation surface 28 on the first conductive-type semiconductor layer 22 of the light-emitting structure 20. The semiconductor light-emitting device 200 shown in FIGS. 22 through 23 may include the light radiation surface 28a on the second conductive-type semiconductor layer 26 of the light-emitting structure 20.

FIGS. 24 and 25 are cross-sectional views illustrating a semiconductor light-emitting package that includes the semiconductor light-emitting device 100 according to an embodiment of the inventive concept.

Referring to FIG. 24, a semiconductor light-emitting device package 1000 includes a lens unit 500 that surrounds the semiconductor light-emitting device 100 mounted on a package substrate 300.

An inside of the lens unit 500 may be filled with, for example, silicon resin, epoxy resin, plastic, or glass. Additionally, a refraction member may be further included in the inside of the lens unit 500. The refraction member may refract or reflect light which is emitted from the semiconductor light-emitting device 100.

The semiconductor light-emitting device 100 may correspond to the semiconductor light-emitting devices 100a through 100f shown in FIGS. 8 through 18.

A first electrode of the semiconductor light-emitting device 100 may be electrically connected to a first conductive region 320 of the package substrate 300. A second electrode of the semiconductor light-emitting device 100 may be electrically connected to a second conductive region 340 of the package substrate 300.

The package substrate 300 may include a metal which has high conductivity compared to plastic and ceramics. In order to maximize the high heat protection characteristics of the package substrate 300, the first conductive region 320 and the second conductive region 340 may be respectively formed of metal. For example, the first conductive region 320 and the second conductive region 340 may be formed of at least one material selected from among Al, Cu, Mg, Zn, Ti, tantalum (Ta), hafnium (Hf), niobium (Nb), MN, SiC, and an alloy thereof.

As the first conductive region 320 and the second conductive region 340 are formed of metal, the first conductive region 320 and the second conductive region 340 may function to support the semiconductor light-emitting device 100, and may also function as a heat sink that emits heat generated from the semiconductor light-emitting device 100 to outside.

The first electrode and the first conductive region 320 may be bonded by using a eutectic die attach process. The second electrode and the second conductive region 340 may be electrically connected to each other via a bonding wire 400.

Referring to FIG. 25, a light-emitting device package 1002 may include a package body 360 which restricts a cavity 362, a resin layer 510 which fills the cavity 362, and the lens unit 500 which is disposed on the package body 360 and the resin layer 510.

The package body 360 may be formed of a translucent material. The package body 360 may be formed of silicon resin, epoxy resin, or glass.

The resin layer 510 may include translucent resin such as silicon resin or epoxy resin. For example, the resin layer 510 may include at least one type of a phosphor or a diffuser.

The lens unit 500 may collect light which is emitted from the semiconductor light-emitting device 100. The lens unit 500 may be filled with silicon resin, epoxy resin, or glass.

In some embodiments, the resin layer 510 and the lens unit 500 may be formed of the same material in one body. In this case, the resin layer 510 and the lens unit 500 may be simultaneously formed.

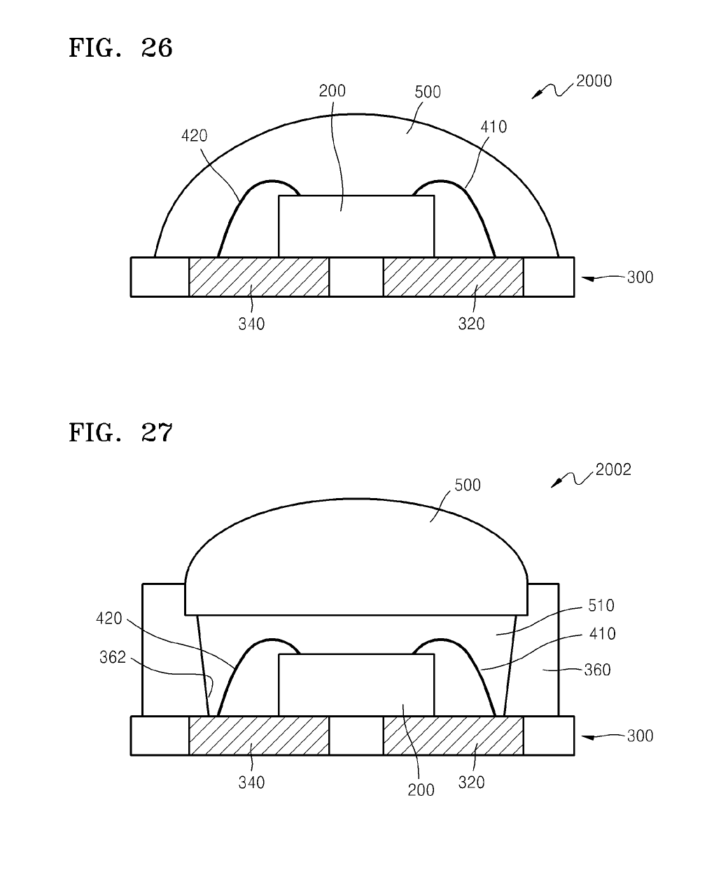

FIGS. 26 and 27 are cross-sectional views illustrating a semiconductor light-emitting package that includes the semiconductor light-emitting device 200 according to another embodiment of the inventive concept.

Referring to FIG. 26, a semiconductor light-emitting package 2000 has generally the same configuration as the semiconductor light-emitting package 1000 illustrated in FIG. 24. However, the semiconductor light-emitting device 200 may correspond to the semiconductor light-emitting device 200 shown in FIGS. 22 and 23. The first and second electrodes of the semiconductor light-emitting device 200 may be electrically and respectively connected to the first conductive region 320 and the second conductive region 340 respectively by using bonding wires 410 and 420.

Referring to FIG. 27, a semiconductor light-emitting package 2002 has generally the same configuration as the semiconductor light-emitting package 1000 illustrated in FIG. 24. However, the semiconductor light-emitting device 200 may correspond to the semiconductor light-emitting device 200 shown in FIGS. 22 and 23. The first and second electrodes of the semiconductor light-emitting device 200 may be electrically and respectively connected to the first conductive region 320 and the second conductive region 340 respectively by using bonding wires 410 and 420.

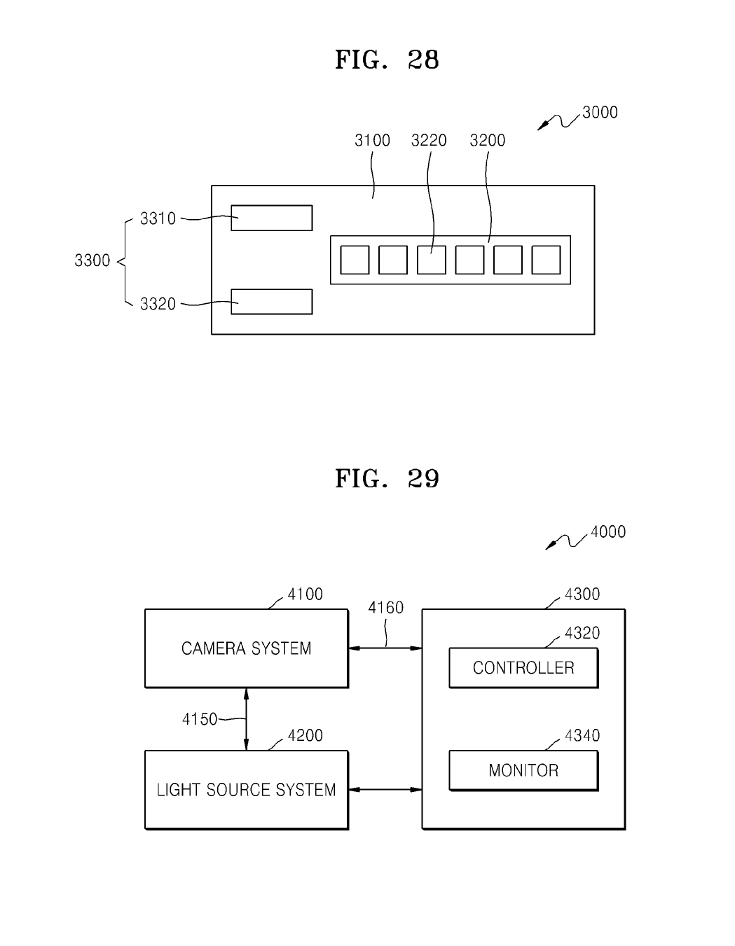

FIG. 28 is a diagram illustrating a dimming system 3000 that includes a semiconductor light-emitting device according to an embodiment of the inventive concept.

Referring to FIG. 28, the dimming system 3000 includes a light-emitting module 3200 and a power-supply unit 3300 which are disposed on a structure 3100.

The light-emitting module 3200 includes a plurality of semiconductor light-emitting devices 3220. The plurality of semiconductor light-emitting devices 3220 include at least one from among the semiconductor light-emitting devices 100a through 100f and 200 described with reference to FIGS. 8 through 18, 22, and 23, and the semiconductor light-emitting device packages 1000, 1002, 2000, and 2002 described with reference to FIGS. 24 through 27.

The power-supply unit 3300 includes an interface 3310 for receiving power, and a power-control unit 3320 for controlling the power supplied from the light-emitting module 3200. The interface 3310 may include a fuse for shutting off over current and an electromagnetic interference (EMI) filter for suppressing an EMI signal. The power-control unit 3320 includes a rectifying unit and a smoothing unit for converting an alternating current (AC) into a direct current (DC) when AC power is input, and a constant-voltage control unit for converting a voltage into a voltage which is suitable for the light-emitting module 3200. The power-supply unit 3300 may include a feedback circuit apparatus which compares an amount of light emitted respectively from a plurality of the semiconductor light-emitting devices to a predefined amount of light, and a memory apparatus for storing information regarding brightness, color rendering, and so on.

The dimming system 3000 may be used as a back-light unit (BLU) for a display apparatus such as a liquid-crystal display (LCD) apparatus that includes an image panel, indoor lighting such as a lamp or flat-panel lighting, or outdoor lighting such as a street lamp, a sign board, or a light panel. The dimming system 3000 may also be used for various light systems for vehicles, for example, a car, a ship, or an aircraft, home appliances such as a TV or a refrigerator, or a medical apparatus.

FIG. 29 is a block diagram illustrating an optical processing system 4000 that includes the semiconductor light-emitting device according to an embodiment of the inventive concept.

Referring to FIG. 29, the optical processing system 4000 includes a camera system 4100, a light source system 4200, and a data processing and analysis system 4300.

The camera system 4100 may be disposed to directly contact a subject or to be separate from a subject by a predefined distance. In some embodiments, the subject may be a part of skin or a tissue such as a treatment area. The camera system 4100 is connected to the light source system 4200 via a light guide 4150. The light guide 4150 may include an optical-fiber light guide that allows light transmission or a liquid light guide.

The light source system 4200 provides light that is incident of the subject via the light guide 4150. The light source system 4200 includes at least one from among the semiconductor light-emitting devices 100a through 100f and 200, which are described by referring to FIGS. 8 through 18, 22, and 23, and the semiconductor light-emitting device packages 1000, 1002, 2000, and 2002, which are described by referring to FIGS. 24 through 27. In some embodiments, an infrared ray may be generated and oscillated by the light source system 4200, and irradiated on the skin or tissue.

The camera system 4100 is connected to the data processing and analysis system 4300 via a cable 4160. A video signal which is output from the camera system 4100 may be transmitted to the data processing and analysis system 4300 via the cable 4160. The data processing and analysis system 4300 includes a controller 4320 and a monitor 4340. The data processing and analysis system 4300 may process, analyze, and store the video signal which is transmitted from the camera system 4100.

The optical processing system 4000 illustrated in FIG. 29 may be used in skin diagnosis, medical treatment apparatuses, disinfection apparatuses, sterilization apparatuses, cleaning apparatuses, operation equipment, beauty medical equipment, light systems, information detection apparatuses, and so on.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light-emitting device, comprising:
a substrate;
a light-emitting structure that comprises:
a first conductive-type semiconductor layer, an active layer, a second conductive-type semiconductor layer are disposed on the substrate, a first region, a second region, and a light radiation surface on one of the first and second conductive-type semiconductor layers,
wherein only the first conductive-type semiconductor layer remains on the substrate in the first region when a part of the second conductive-type semiconductor layer and a part of the active layer are removed,
wherein the active layer is disposed between the first and second conductive-type semiconductor layers on the substrate in the second region; and
a first electrode and a second electrode which are electrically connected to the first and second conductive-type semiconductor layers respectively so that the first and second electrodes are connected to a different conductive-type semiconductor layer from each other,
wherein the second electrode is disposed in the first region on the light radiation surface of the light-emitting structure.

2. The semiconductor light-emitting device of claim 1, wherein the second electrode is disposed adjacent to an edge of an upper surface of the light-emitting structure.

3. The semiconductor light-emitting device of claim 1, wherein the second electrode is disposed adjacent to a side of the upper surface of the light-emitting structure.

4. The semiconductor light-emitting device of claim 3, further comprising:
a fluorescent body that covers at least a part of the second region on the light radiation surface of the light-emitting structure,
wherein the fluorescent body is separate from the side of the upper surface of the light-emitting structure which the second electrode is adjacent to.

5. The semiconductor light-emitting device of claim 3, further comprising:
an insulating layer covering a side of the active layer which is exposed at a boundary between the first and second regions.

6. The semiconductor light-emitting device of claim 5, wherein the insulating layer extends from the side of the active layer which is exposed at the boundary between the first and second regions to cover the first conductive semiconductor layer in the first region.

7. The semiconductor light-emitting device of claim 6, further comprising:
a non-reflective metal layer on the insulating layer.

8. The semiconductor light-emitting device of claim 1, further comprising:
a fluorescent body covering at least a part of the second region on the light radiation surface of the light-emitting structure, and extending from a boundary between the first and second regions to the first region to cover a part of the first region.

9. The semiconductor light-emitting device of claim 8, wherein an edge of the first region of the fluorescent body is separate from the boundary between the first and second regions and located within 20 μm from the boundary between the first and second regions.

10. The semiconductor light-emitting device of claim 8, wherein the fluorescent body further covers a part of the second electrode.

11. The semiconductor light-emitting device of claim 1, wherein:
the second electrode contacts the first conductive-type semiconductor layer in the first region, and
the first electrode is electrically connected to the second conductive-type semiconductor layer, and the substrate is a conductive substrate that functions as the first electrode.

12. The semiconductor light-emitting device of claim 1, further comprising:
a reflective metal layer between the second conductive-type semiconductor layer and the first electrode.

13. The semiconductor light-emitting device of claim 1, wherein the light-emitting structure further comprises:
a third region separate from the first region and, when a part of the second conductive-type semiconductor layer and a part of the active layer are removed, to expose the first conductive-type semiconductor layer, and
a current dispersion layer that is disposed in both the first and second regions of the light-emitting structure, and
wherein the first electrode is disposed in the third region to contact the first conductive-type semiconductor layer, and
wherein the second electrode is connected to the second conductive-type semiconductor layer via the current dispersion layer.

14. A semiconductor light-emitting device, comprising:
a conductive substrate;
a light-emitting structure that comprises:
a first conductive-type semiconductor layer, an active layer, a second conductive-type semiconductor layer are disposed on the substrate, a first region and a second region,
wherein only the first conductive-type semiconductor layer remains on the substrate in the first region when a part of the second conductive-type semiconductor layer and a part of the active layer are removed, and
wherein the active layer is disposed between the first and second conductive-type semiconductor layers on the substrate in the second region;
an insulating layer covering a side of the active layer which is exposed at a boundary between the first and second regions;
a pad electrode disposed in the first region and is electrically connected to the second conductive-type semiconductor layer; and
a fluorescent body covering the second region,
wherein the conductive substrate is electrically connected to the first conductive-type semiconductor layer.

15. The semiconductor light-emitting device of claim 14, wherein:
the pad electrode adjacent to an edge of an upper surface of the second conductive-type semiconductor layer, and
the fluorescent body extending from the boundary between the first and second regions to the first region, covering a part of an upper surface of the second conductive-type semiconductor layer in the first region, and is separate from an edge of the upper surface of the second conductive-type semiconductor layer which the second electrode is adjacent to.

16. A semiconductor light-emitting package comprising a semiconductor light-emitting device, the semiconductor light-emitting device including:
a conductive substrate;
a light-emitting structure that comprises:
a first conductive-type semiconductor layer, an active layer, a second conductive-type semiconductor layer are disposed on the substrate, a first region and a second region,
wherein only the first conductive-type semiconductor layer remains on the substrate in the first region when a part of the second conductive-type semiconductor layer and a part of the active layer are removed, and
wherein the active layer is disposed between the first and second conductive-type semiconductor layers on the substrate in the second region;
an insulating layer covering a side of the active layer which is exposed at a boundary between the first and second regions;
a pad electrode disposed in the first region and is electrically connected to the second conductive-type semiconductor layer; and
a fluorescent body covering the second region,
wherein the conductive substrate is electrically connected to the first conductive-type semiconductor layer.

17. The semiconductor light-emitting package of claim 16, wherein the fluorescent body is formed of a material selected from a yttrium aluminum garnet (YAG)-based material, a terbium aluminum garnet (TAG)-based material, a sulfide-based material, a nitride-based material, or a quantum-point fluorescent material.

18. The semiconductor light-emitting package of claim 16, further comprising:
a reflective metal disposed on the second region on the second conductive-type semiconductor layer.

19. The semiconductor light-emitting package of claim 16, wherein the light-emitting structure further comprises a light radiation surface disposed in a part of the first and second regions.

20. The semiconductor light-emitting package of claim 19, wherein the fluorescent body covers at least a part of the second region on the light radiation surface of the light-emitting structure.
